(19) United States
(12) Patent Application Publication
(10) Pub. No.: US 2009/0103351 A1
(43) Pub. Date: Apr. 23, 2009

(54) Integrated Circuit, Method of Manufacturing an Integrated Circuit, and Memory Module

(76) Inventors: Cay-Uwe Pinnow, Dresden (DE); Wolfgang Raberg, Sauerlach (DE); Faiz Dahmani, La Varenne Saint-Hilaire (FR)

Correspondence Address: SLATER & MATSIL, L.L.P., 17950 PRESTON ROAD, SUITE 1000, DALLAS, TX, 75252, US

(21) Appl. No.: 11/877,558

(22) Filed: Oct. 23, 2007

(51) Int. Cl. G11C 11/24; H01G 9/00

(52) U.S. Cl. 365/149; 29/25.03

(57) ABSTRACT

According to one embodiment of the present invention, an integrated circuit includes at least one memory device including: a reactive electrode layer, an inert electrode layer, and a solid electrolyte layer being disposed between the reactive electrode layer and the inert electrode layer; at least one interface layer being disposed between the solid electrolyte layer and the reactive electrode layer and/or between the solid electrolyte layer and the inert electrode layer. The material parameters of the at least one interface layer are chosen such that a crystallization of the solid electrolyte layer is at least partially suppressed.

### BRIEF DESCRIPTION OF THE DRAWINGS

In the drawings, like reference characters generally refer to the same part throughout the different views. The drawings are not necessarily to scale, emphasis instead generally being placed upon illustrating the principals of the invention. In the following description, various embodiments of the invention are described with reference to the following drawings, in which:

FIG. 1A shows a cross-sectional view of a solid electrolyte memory device set to a first memory state;

FIG. 1B shows a cross-sectional view of a solid electrolyte memory device set to a second switching state;

FIG. 2 shows a cross-sectional view of a memory device;

FIG. 3 shows a cross-sectional view of a memory device according to one embodiment of the present invention;

FIG. 4 shows a cross-sectional view of a memory device according to one embodiment of the present invention;

FIG. 5 shows a flow chart of a method of manufacturing a memory device according to one embodiment of the present invention;

FIG. 6A shows a cross-sectional view of a processing state of a method of fabricating a memory device according to one embodiment of the present invention;

FIG. 6B shows a cross-sectional view of a processing state of a method of fabricating a memory device according to one embodiment of the present invention;

FIG. 6C shows a cross-sectional view of a processing state of a method of fabricating a memory device according to one embodiment of the present invention;

FIG. 6D shows a cross-sectional view of a processing state of a method of fabricating a memory device according to one embodiment of the present invention;

FIG. 6E shows a cross-sectional view of a processing state of a method of fabricating a memory device according to one embodiment of the present invention;

FIG. 7A shows a memory module according to one embodiment of the present invention; and

FIG. 7B shows a memory module according to one embodiment of the present invention.

### DETAILED DESCRIPTION OF ILLUSTRATIVE EMBODIMENTS

According to one embodiment of the present invention, an integrated circuit includes at least one memory device including a reactive electrode layer, an inert electrode layer, and a solid electrolyte layer being disposed between the reactive electrode layer and the inert electrode layer. At least one interface layer is disposed between the solid electrolyte layer and the reactive electrode layer and/or between the solid electrolyte layer and the inert electrode layer. The material parameters of the at least one interface layer are chosen such that a crystallization of the solid electrolyte layer is at least partially suppressed or even completely prevented.

According to one embodiment of the present invention, the crystallization of the solid electrolyte layer is caused by elevating the temperature of the solid electrolyte layer. However, the present invention is not restricted thereto. The crystallization of the solid electrolyte layer may also be caused by other phenomena. For sake of simplicity, it will be assumed in the following description that the crystallization of the solid electrolyte layer is caused by an annealing of the solid electrolyte layer.

According to one embodiment of the present invention, a memory device includes a reactive electrode layer, an inert electrode layer, and a solid electrolyte layer being disposed between the reactive electrode layer and the inert electrode layer. At least one interface layer is disposed between the solid electrolyte layer and the reactive electrode layer and/or between the solid electrolyte layer and the inert electrode layer. The material parameters of the at least one interface layer are chosen such that a crystallization of the solid electrolyte layer due to an annealing of the solid electrolyte layer is at least partially suppressed or even completely prevented.

According to one embodiment of the present invention, the material of the at least one interface layer comprises amorphous material or pseudo-amorphous material or consists of amorphous material or pseudo-amorphous material.

According to one embodiment of the present invention, the crystallization characteristics of the material of the at least one interface layer and the crystallization characteristics of the solid electrolyte layer differ from each other.

According to one embodiment of the present invention, the crystallization characteristics of the material of the at least one interface layer differ from the crystallization characteristics of the solid electrolyte layer in terms of lattice parameters and space group (crystal structure).

According to one embodiment of the present invention, the material of at least one interface layer does not act as a diffusion barrier for the reactive material (i.e., the migration of metallic material, like Ag or Cu, into the solid electrolyte layer is possible).

According to one embodiment of the present invention, the material of at least one interface layer comprises binary metallic material, ternary metallic material or quaternary metallic material including at least one transition metal, or consists of these materials.

According to one embodiment of the present invention, the material of at least one interface layer comprises binary semiconducting material, ternary semiconducting material or quaternary semiconducting material including at least one transition metal, or consists of these materials.

According to one embodiment of the present invention, the material of at least one interface layer comprises Cu₁₋ₓRuₓ, Cu, Ru, Cu—N, Cu—O, Ru—O, Ru—N, Ru—O—N, Cu—Ru—O—N, Cu—Ru—N, Cu—Ru—O, Mo—N, Mo—N—Cu, Mo or any combination of these materials.

According to one embodiment of the present invention, the at least one interface layer comprises a first interface layer being disposed between the solid electrolyte layer and the reactive electrode layer, and a second interface layer being disposed between the solid electrolyte layer and the inert electrode layer.

According to one embodiment of the present invention, the thickness of the first interface layer and/or of the second interface layer is less than about 5 nm.

According to one embodiment of the present invention, the thickness of the first interface layer and/or of the second interface layer is less than about 2 nm.

According to one embodiment of the present invention, the thicknesses of the first interface layer and of the second interface layer are the same.

According to one embodiment of the present invention, the material of the first interface layer differs from the material of the second interface layer.

According to one embodiment of the present invention, the solid electrolyte layer is completely encapsulated by the at least one interface layer.

According to one embodiment of the present invention, the solid electrolyte layer comprises sulfide based chalcogenide material or consists of this material.

According to one embodiment of the present invention, the reactive electrode layer comprises silver or consists of silver.

According to one embodiment of the present invention, the thickness of the solid electrolyte layer ranges from about 5 nm to about 500 nm.

According to one embodiment of the present invention, the thickness of the reactive electrode layer ranges from about 10 nm to about 100 nm.

According to one embodiment of the present invention, an integrated circuit is provided including at least one memory device which comprises a reactive electrode means, an inert electrode means, and a solid electrolyte means being disposed between the reactive electrode means and the inert electrode means. The memory device further comprises at least one interface means being disposed between the solid electrolyte means and the reactive electrode means and/or between the solid electrolyte means and the inert electrode means. The material parameters of the at least one interface means are chosen such that crystallization of the solid electrolyte means due to an annealing of the solid electrolyte means is at least partially suppressed.

The reactive electrode means, the inert electrode means, the solid electrolyte means, and the at least one interface means may, for example, be structured or unstructured layers.

According to one embodiment of the present invention, a memory module is provided including an integrated circuit or a memory device according to one embodiment of the present invention.

According to one embodiment of the present invention, the memory module is stackable.

The present invention further provides a method of manufacturing an integrated circuit including a memory device, including: a) forming a composite structure including an inert electrode layer, a solid electrolyte layer and a reactive electrode layer which are stacked above each other in this order, b) forming a first interface layer on or above the inert electrode layer before forming the solid electrolyte layer, and/or c) forming a second interface layer on or above the solid electrolyte layer before forming the reactive electrode layer. The material parameters of the first interface layer and/or of the second interface layer are chosen such that a crystallization of the solid electrolyte layer due to annealing of the solid electrolyte layer is at least partially suppressed.

An embodiment of the present invention further provides a method of manufacturing an integrated circuit including a memory device, including: a) forming a composite structure including a reactive electrode layer, a solid electrolyte layer and an inert electrode layer which are stacked above each other in this order, b) forming a first interface layer on or above the reactive electrode layer before forming the solid electrolyte layer, and/or c) forming a second interface layer on or above the solid electrolyte layer before forming the inert electrode layer. The material parameters of the first interface layer and/or of the second interface layer are chosen such that a crystallization of the solid electrolyte layer due to annealing of the solid electrolyte layer is at least partially suppressed.

The present invention further provides a method of a manufacturing memory device, including: a) forming a composite structure including an inert electrode layer, a solid electrolyte layer and a reactive electrode layer that are stacked above each other in this order, b) forming a first interface layer on or above the inert electrode layer before forming the solid electrolyte layer, and/or c) forming a second interface layer on or above the solid electrolyte layer before forming the reactive electrode layer. The material parameters of the first interface layer and/or of the second interface layer are chosen such that a crystallization of the solid electrolyte layer due to annealing of the solid electrolyte layer is at least partially suppressed.

An embodiment of the present invention further provides a method of manufacturing a memory device, including: a) forming a composite structure including a reactive electrode layer, a solid electrolyte layer and an inert electrode layer which are stacked above each other in this order, b) forming a first interface layer on or above the reactive electrode layer before forming the solid electrolyte layer, and/or c) forming a second interface layer on or above the solid electrolyte layer before forming the inert electrode layer. The material parameters of the first interface layer and/or of the second interface layer are chosen such that a crystallization of the solid electrolyte layer due to annealing of the solid electrolyte layer is at least partially suppressed.

According to one embodiment of the present invention, the solid electrolyte layer is provided containing metallic material during its formation by codeposition (e.g., co-sputtering) the solid electrolyte layer material with a metallic material target.

According to one embodiment of the present invention, the codeposition material (e.g., sputtering target) includes Ag₂S, Ag, Cu₂S, or Cu or consists of at least one of the materials.

According to one embodiment of the present invention, the solid electrolyte layer is provided including metallic material after its formation.

According to one embodiment of the present invention, the inert electrode layer is subjected to a cleaning process before the first interface layer is formed.

According to one embodiment of the present invention, a method of manufacturing an integrated circuit including a memory device is provided, including: forming an inert electrode layer; forming a first interface layer on the inert electrode layer; forming a solid electrolyte layer on the first interface layer; forming a reactive electrode layer on the solid electrolyte layer; and forming a second interface layer on the solid electrolyte layer. The material parameters of the first interface layer and the second interface layer are chosen such that a crystallization of the solid electrolyte layer due to an annealing of the solid electrolyte layer is at least partially suppressed.

According to one embodiment of the present invention, a method of manufacturing a memory device is provided, including: forming an inert electrode layer; forming a first interface layer on or above the inert electrode layer; forming a solid electrolyte layer on or above the first interface layer; forming a second interface layer on or above the solid electrolyte layer; and forming a reactive electrode layer on or above the second interface layer. The material parameters of the first interface layer and the second interface layer are chosen such that a crystallization of the solid electrolyte layer due to annealing of the solid electrolyte layer is at least partially suppressed.

According to one embodiment of the present invention, a method of manufacturing a memory device is provided, including: forming a reactive electrode layer; forming a first interface layer on or above the reactive electrode layer; forming a solid electrolyte layer on or above the first interface layer; forming a second interface layer on or above the solid electrolyte layer; and forming an inert electrode layer on or above the second interface layer. The material parameters of the first interface layer and the second interface layer are chosen such that a crystallization of the solid electrolyte layer due to annealing of the solid electrolyte layer is at least partially suppressed.

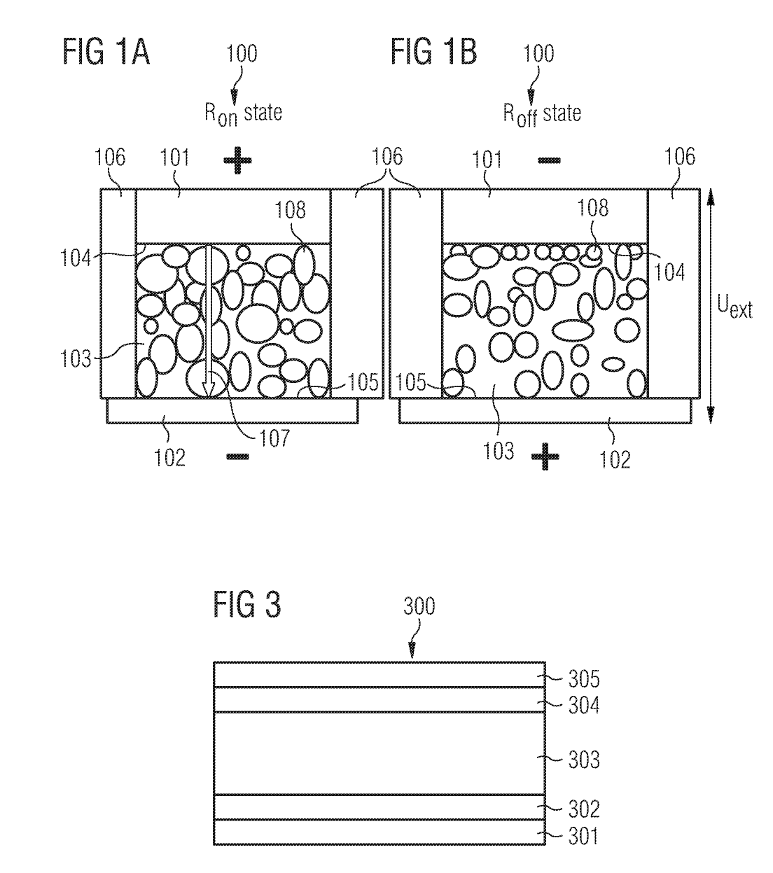

Since the embodiments of the present invention can be applied to programmable metallization cell devices (PMC) (e.g., solid electrolyte devices like CBRAM (conductive bridging random access memory) devices), in the following description, making reference to FIGS. 1A and 1B, a basic principle underlying embodiments of CBRAM devices will be explained.

As shown in FIG. 1A, a CBRAM cell 100 includes a first electrode 101, a second electrode 102, and a solid electrolyte block (in the following also referred to as ion conductor block) 103 which includes the active material and which is sandwiched between the first electrode 101 and the second electrode 102. This solid electrolyte block 103 can also be shared between a large number of memory cells (not shown here). The first electrode 101 contacts a first surface 104 of the ion conductor block 103, the second electrode 102 contacts a second surface 105 of the ion conductor block 103. The ion conductor block 103 is isolated against its environment by an isolation structure 106. The first surface 104 usually is the top surface, the second surface 105 the bottom surface of the ion conductor 103. In the same way, the first electrode 101 generally is the top electrode, and the second electrode 102 the bottom electrode of the CBRAM cell. One of the first electrode 101 and the second electrode 102 is a reactive electrode, the other one an inert electrode. Here, the first electrode 101 is the reactive electrode, and the second electrode 102 is the inert electrode. In this example, the first electrode 101 includes silver (Ag), the ion conductor block 103 includes silver-doped chalcogenide material, the second electrode 102 includes tungsten (W), and the isolation structure 106 includes SiO₂. The present invention is however not restricted to these materials. For example, the first electrode 101 may alternatively or additionally include copper (Cu) or zinc (Zn), and the ion conductor block 103 may alternatively or additionally include copper-doped chalcogenide material. Further, the second electrode 102 may alternatively or additionally include nickel (Ni) or platinum (Pt), iridium (Ir), rhenium (Re), tantalum (Ta), titanium (Ti), ruthenium (Ru), molybdenum (Mo), vanadium (V), conductive oxides, silicides, and nitrides of the aforementioned compounds, and can also include alloys of the aforementioned metals or materials. The thickness of the ion conductor 103 may, for example, range between about 5 nm and about 500 nm. The thickness of the first electrode 101 may, for example, range between about 10 nm and about 100 nm. The thickness of the second electrode 102 may, for example, range between about 5 nm and about 500 nm, between about 15 nm to about 150 nm, or between about 25 nm and about 100 nm.

In the context of this description, chalcogenide material (ion conductor) is to be understood, for example, as any compound containing oxygen, sulphur, selenium, and/or tellurium. In accordance with one embodiment of the invention, the ion conducting material is, for example, a compound, which is made of a chalcogenide and at least one metal of the group I or group II of the periodic system, for example, arsenic-trisulfide-silver. Alternatively, the chalcogenide material contains germanium-sulfide (GeSₓ), germanium-selenide (GeSeₓ), tungsten oxide (WOₓ), copper sulfide (CuSₓ) or the like. The ion conducting material may be a solid state electrolyte.

Furthermore, the ion conducting material can be made of a chalcogenide material containing metal ions, wherein the metal ions can be made of a metal, which is selected from a group consisting of silver, copper and zinc or of a combination or an alloy of these metals. It is to be understood that the present invention is not restricted to the above-mentioned materials and thicknesses.

If a voltage as indicated in FIG. 1A is applied across the ion conductor block 103, a redox reaction is initiated which drives Ag⁺ ions out of the first electrode 101 into the ion conductor block 103 where they are reduced to Ag, thereby forming Ag rich clusters 108 within the ion conductor block 103. If the voltage applied across the ion conductor block 103 is applied for an enhanced period of time, the size and the number of Ag rich clusters within the ion conductor block 103 is increased to such an extent that a conductive bridge 107 between the first electrode 101 and the second electrode 102 is formed. In case that a voltage is applied across the ion conductor 103 as shown in FIG. 1B (inverse voltage compared to the voltage applied in FIG. 1A), a redox reaction is initiated which drives Ag⁺ ions out of the ion conductor block 103 into the first electrode 101 where they are reduced to Ag. As a consequence, the size and the number of Ag rich clusters within the ion conductor block 103 is reduced, thereby erasing the conductive bridge 107.

In order to determine the current memory status of a CBRAM cell, for example, a sensing current is routed through the CBRAM cell. The sensing current experiences a high resistance in case no conductive bridge 107 exists within the CBRAM cell, and experiences a low resistance in case a conductive bridge 107 exists within the CBRAM cell. A high resistance may for example represent “0”, whereas a low resistance represents “1”, or vice versa. The memory status detection may also be carried out using sensing voltages.

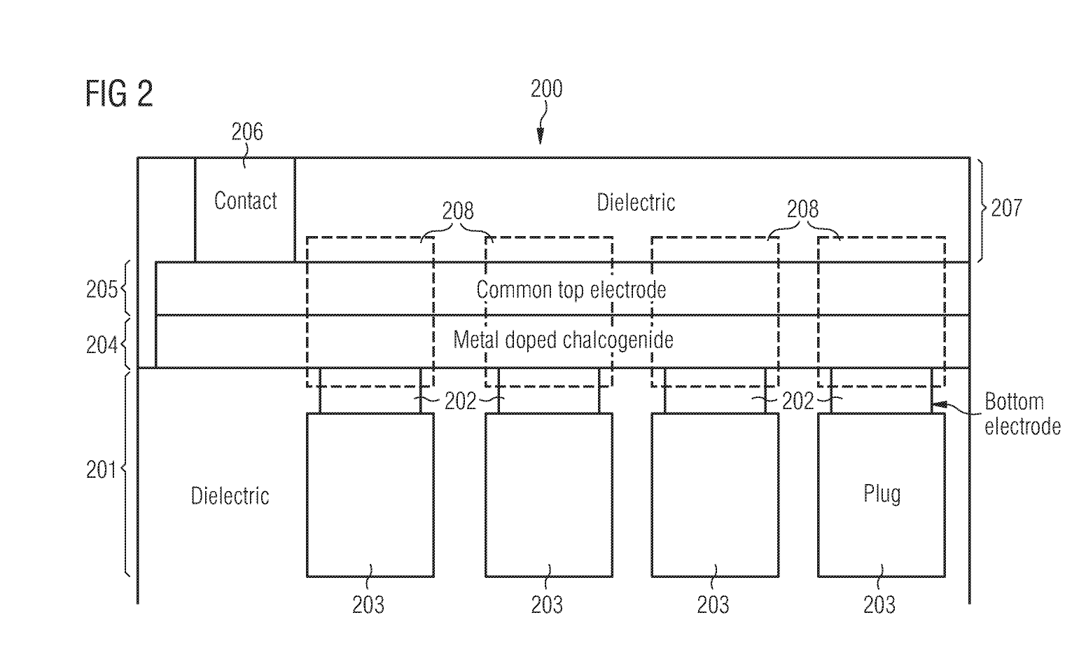

FIG. 2 shows an embodiment 200 of a solid electrolyte memory device. The memory device 200 includes a first isolation layer 201, into which bottom electrodes 202 are embedded. The bottom surfaces of the bottom electrodes 202 are contacted by plugs 203, which are also embedded into the first isolation layer 201. The plugs 203 provide an electrical contact between the bottom electrodes 202 and bit lines, which are embedded into a substrate (not shown), which is arranged below the first isolation layer 201. The memory device 200 further includes a solid electrolyte layer 204 being arranged on the first isolation layer 201. A common top electrode layer 205 is arranged on the solid electrolyte layer 204. The top electrode layer 205 is contacted by a contact 206, which is embedded into a second isolation layer 207 being arranged on the top electrode layer 205.

The first isolation layer 201 and the second isolation layer 207 may, for example, include or consist of dielectric material, the bottom electrodes 202, for example, include or consist of tungsten (W), the plugs 203, for example, include or consist of semiconducting material, the solid electrolyte layer 204, for example, includes or consists of chalcogenide based material, the top electrode layer 205, for example, includes or consists of silver (Ag), and the contact 206, for example, includes or consists of tungsten (W).

Each section of the memory device 200 denoted by reference numeral 208 may be interpreted as a solid electrolyte memory cell as shown in FIGS. 1a and 1b. The only difference is that no isolation structures are provided between neighboring solid electrolyte memory cells 208; instead, the solid electrolyte memory cells 208 share a common top electrode layer 205 and a common solid electrolyte layer 204.

When manufacturing the memory device 200, the following problems may arise: a) when annealing the memory device 200 (which may, for example, be necessary during a back end of line process in order to finalize the memory device 200 by adding additional wiring layers or the like (not shown)), the solid electrolyte layer 204 may crystallize, in particular at the interfaces between the solid electrolyte layer 204 and the top electrode layer 205 or between the solid electrolyte layer 204 and the bottom electrodes 202; b) when growing the top electrode layer 205 on the solid electrolyte layer 204, the material of the solid electrolyte layer 204 may influence the growth of the top electrode layer 205 in a negative way (depending on how well the material of the solid electrolyte layer 204 “fits” to the material of the top electrode layer 205), i.e., irregularities in the growth of the top electrode layer 205 are the consequence. Both problems may result in an unevenness of the top surface of the top electrode layer 205. An unevenness of the top surface of the top electrode layer 205, however, means that the back end of line process (i.e., the finalizing of the memory device 200) will be more complicated. Further, problem a) may result in a junction shortening.

FIG. 3 shows a cross-sectional view of a memory device 300 according to one embodiment of the present invention which avoids the above-mentioned problems. The memory device 300 includes an inert electrode layer (bottom electrode layer) 301, a first interface layer 302 disposed on the inert electrode layer 301, a solid electrolyte layer 303 disposed on the first interface layer 302, a second interface layer 304 disposed on the solid electrolyte layer 303, and a reactive electrode layer 305 (top electrode layer) being disposed on the second interface layer 304. The material of the first interface layer 302 and the second interface layer 304 is chosen such that a crystallization of the solid electrolyte layer 303 due to an annealing of the solid electrolyte layer 303 is at least partially suppressed or completely prevented.

In order to suppress the above-mentioned crystallization, the material of the first interface layer 302 and the second interface layer 304 may, for example, include amorphous material or pseudo-amorphous material (i.e., amorphous material containing a certain amount of nanocrystalline precipitations) or consist of amorphous material or pseudo-amorphous material, respectively. According to one embodiment of the present invention, the crystallization characteristics of the material of the first interface layer 302 and the second interface layer 304 and the crystallization characteristics of the solid electrolyte layer 303 differ from each other. For example, the crystallization characteristics may differ from each other in terms of the lattice, the lattice parameters, and the space group. This difference may, for example, be reflected by a lattice parameter difference of at least 3% between the solid electrolyte layer lattice and the first interface layer lattice or the second interface layer lattice, or by even a completely different crystalline lattice.

According to one embodiment of the present invention, the material of the first interface layer 302 and the second interface layer 304 includes binary metallic material, ternary metallic material or quaternary metallic material including at least one transition metal, or consists of these materials, respectively. Further, according to one embodiment of the present invention, the material of the first interface layer 302 and the second interface layer 304 include binary semiconducting material, ternary semiconducting material or quaternary semiconducting material including at least one transition metal, or consists of these materials, respectively. According to one embodiment of the present invention, the material of the first interface layer 302 and the second interface layer 304 includes Cu₁₋ₓRuₓ, Cu, Ru, Cu—N, Cu—O, Ru—O, Ru—N, Ru—O—N, Cu—Ru—O—N, Cu—Ru—N, Cu—Ru—O, Mo—N, Mo—N—Cu, Mo or any combination of these materials, respectively. The most preferred material would be Cu—Ru films, containing a large amount of Cu (i.e., more than 50 at %).

According to one embodiment of the present invention, the thicknesses of the first interface layer 302 and of the second interface layer 304 are the same. For example, the thickness of the first interface layer and of the second interface layer may be less than about 5 nm, or even less than about 2 nm.

In the embodiments of the foregoing description, concerning the memory device 300 shown in FIG. 3, the first interface layer 302 and the second interface layer 304 were of the same material. However, the invention is not restricted to this, i.e., the material of the first interface layer 302 may differ from the material of the second interface layer 304. This effects that the top electrode and the bottom electrode is not shortened if the interface layer including metallic material is electrically conducting.

According to one embodiment of the present invention, the solid electrolyte layer 303 is completely encapsulated by material used for the first interface layer 302 and/or used for the second interface layer 304, e.g., amorphous metal including material (i.e., “completely” means that also the sidewalls of the solid electrolyte layer 303 are covered with material used for the first interface layer 302 and/or used for the second interface layer 304). Alternatively, “completely encapsulated” may, for example, mean that the sidewalls of the solid electrolyte layer 303 may, for example be covered with a different material like standard CMOS dielectric material like SiO₂.

According to one embodiment of the present invention, the solid electrolyte layer comprises sulfide based chalcogenide material, or consists of this material. Further, according to one embodiment of the present invention, the reactive electrode layer 305 comprises silver or consists of silver. The thickness of the solid electrolyte layer 303 may, for example, range between about 5 nm to about 500 nm. Further, the thickness of the reactive electrode layer 305 may, for example, range between about 10 nm to about 100 nm. The present invention, however, is not limited to these thickness values.

According to one embodiment of the present invention, the material of the second interface layer 304 is chosen such that it functions like a seed layer for depositing the reactive electrode layer 305, i.e., effects a smooth growth of the reactive electrode layer 305 on the second interface layer 304. In other words, the second interface layer 304 may both prevent or decrease the crystallization in the upper area of the solid electrolyte layer 303 and enable a smooth growth of the reactive electrode layer 305 on the second interface layer 304. Enabling the smooth growth of the reactive electrode layer 305 may be an additional property of the interface layer. In the same way, according to one embodiment of the present invention, the material of the first interface layer 302 is chosen such that the first interface layer 302 both suppresses crystallization in the lower area of the solid electrolyte layer 303 and ensures a smooth growth of the solid electrolyte layer 303 on the first interface layer 302. The solid electrolyte layer 303 may be amorphous during the growth of the second interface layer 304 and also during the growth of the reactive electrode layer 305.

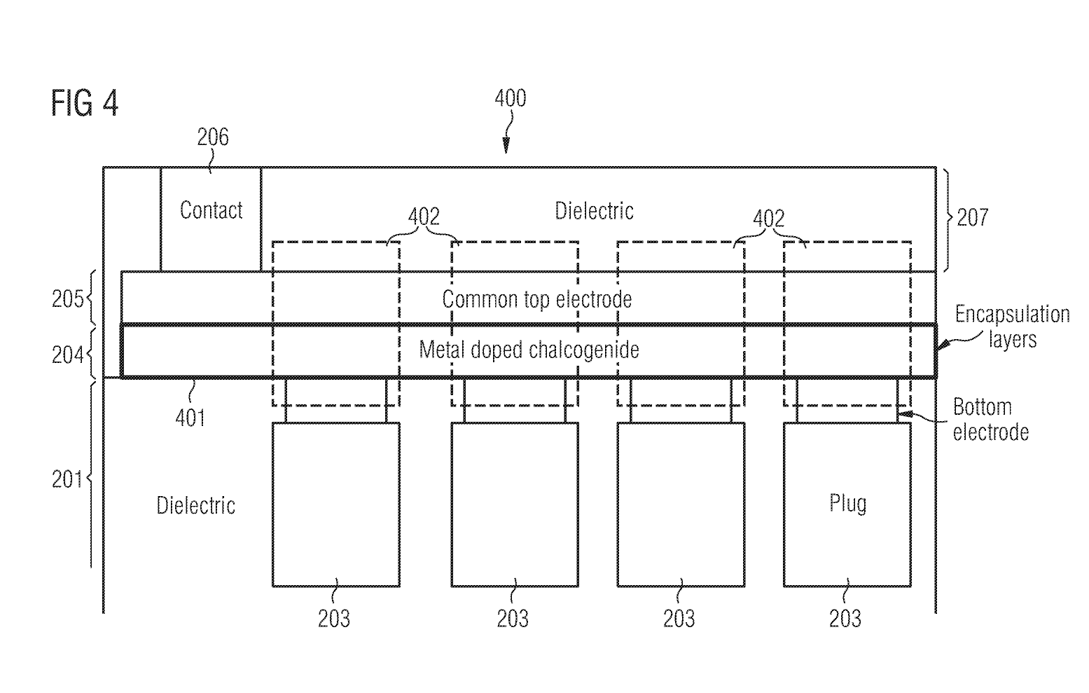

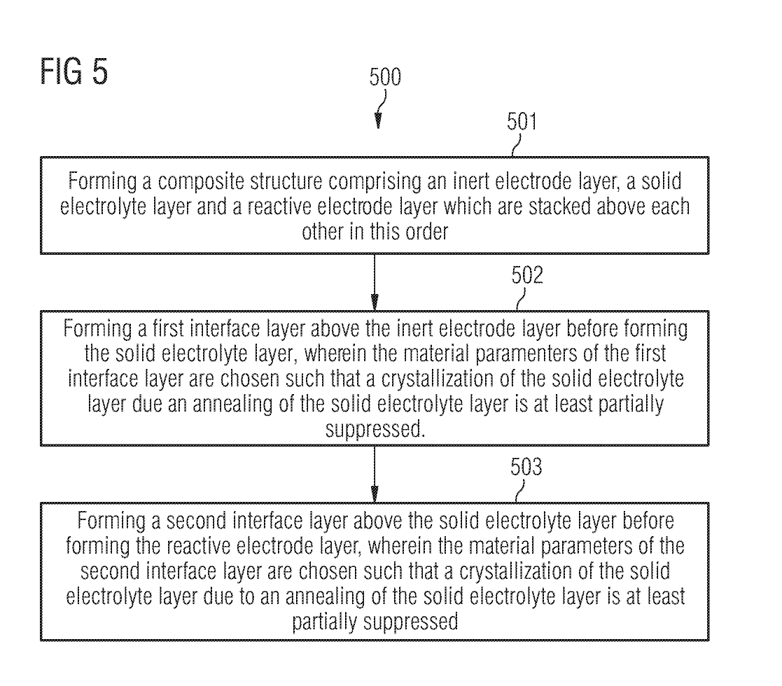

FIG. 4 shows a memory device 400 according to one embodiment of the present invention.

The architecture of the memory device 400 corresponds to the architecture of the memory device 200 shown in FIG. 2. The only difference is that the solid electrolyte layer 204 is completely encapsulated by an encapsulation layer 401. “Completely encapsulated” may, for example, mean that also the sidewalls of the solid electrolyte layer 204 are covered with material used for the first interface layer 302 and/or used for the second interface layer 304. Alternatively, “completely encapsulated” may, for example, mean that the sidewalls of the solid electrolyte layer 204 may, for example, be covered with a different material like standard CMOS dielectric material like SiO₂. The material of the encapsulation layer 401 may be identical to the materials of the first interface layer 302 and the second interface layer 304 discussed in conjunction with the memory device 300 shown in FIG. 3. Each section 402 of the memory device 400 shown in FIG. 4 may be interpreted as a memory cell 300 as shown in FIG. 3.

FIG. 5 shows a flow chart 500 of a method of manufacturing a memory device according to one embodiment of the present invention.

In a first process 501, a composite structure is formed including an inert electrode layer, a solid electrolyte layer and a reactive electrode layer, which are stacked above each other in this order.

In a second process 502, a first interface layer is formed above the inert electrode layer before forming the solid electrolyte layer, wherein the material parameters of the first interface layer are chosen such that a crystallization of the solid electrolyte layer due to annealing of the solid electrolyte layer is at least partially suppressed.

In a third process 503, a second interface layer is formed above the solid electrolyte layer before forming the reactive electrode layer, wherein the material parameters of the second interface layer are chosen such that a crystallization of the solid electrolyte layer due to annealing of the solid electrolyte layer is at least partially suppressed.

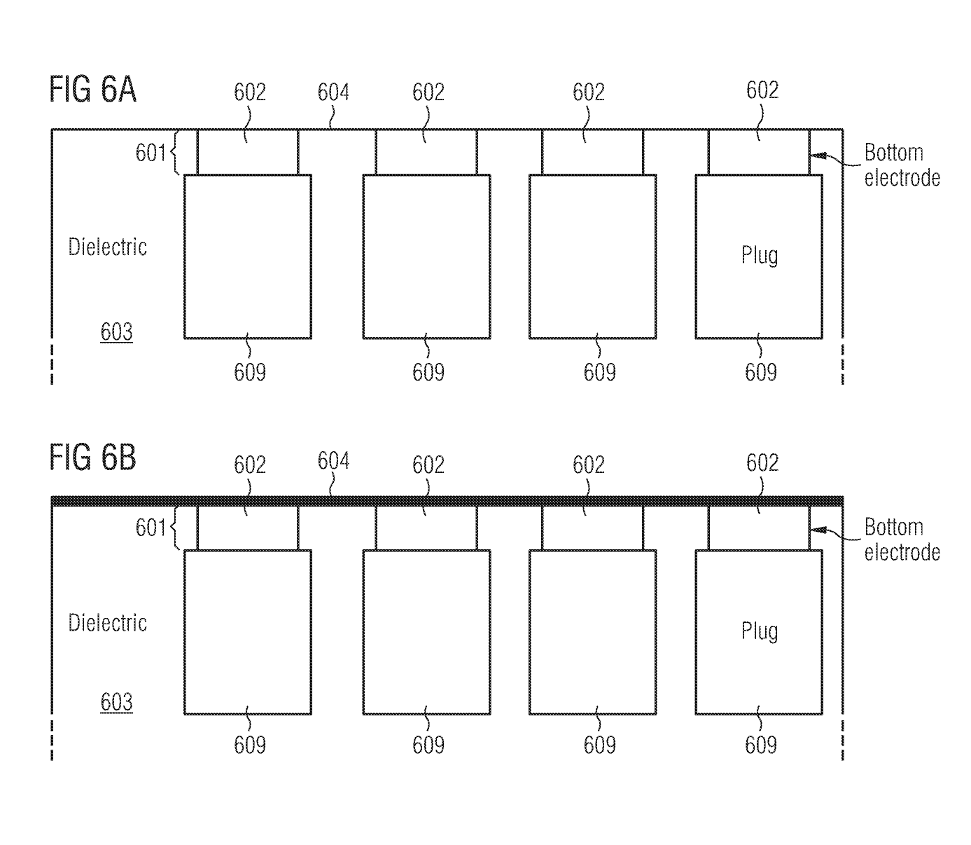

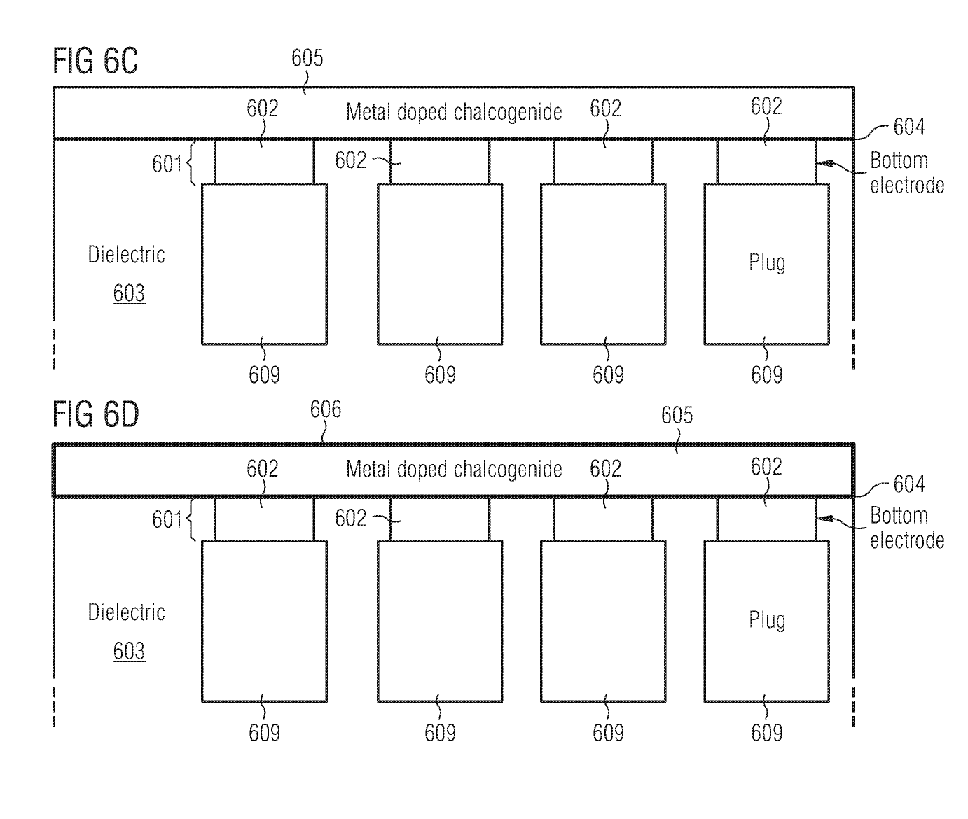

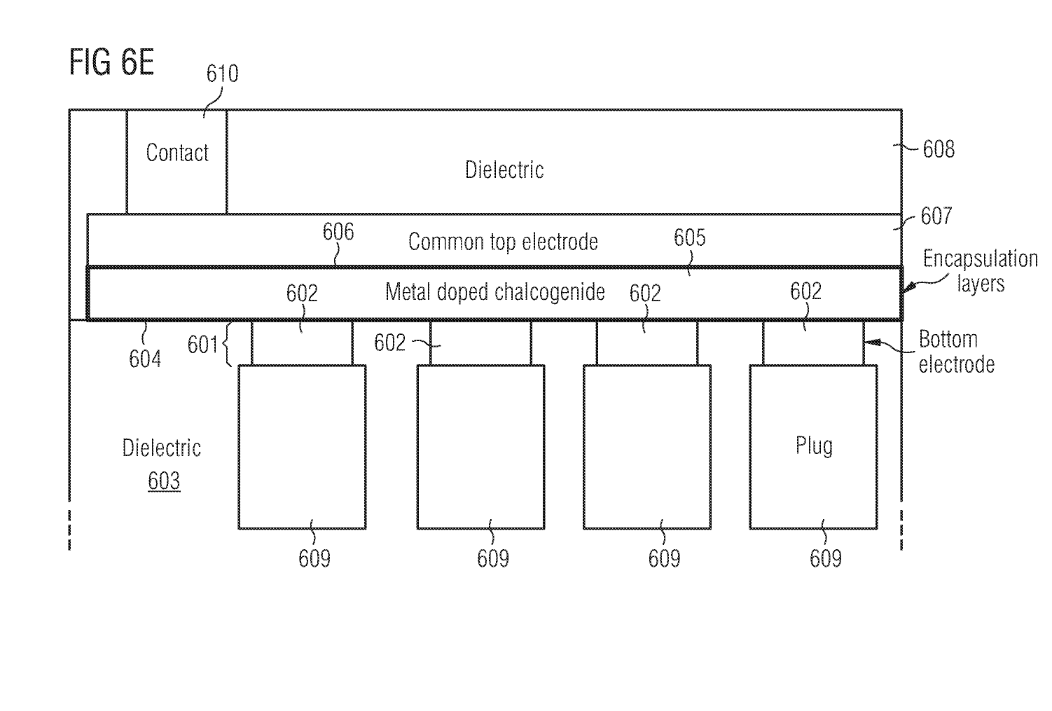

In the following description, making reference to FIGS. 6A to 6E, a method of manufacturing a memory device according to one embodiment of the present invention will be explained.

In a first process (FIG. 6A), an inert electrode layer 601 is formed including several inert electrodes 602 which are isolated against each other by a first isolation layer 603. The inert electrodes 602 are contacted by conductive plugs 609 which are disposed below the inert electrodes 602 and manufactured before manufacturing the inert electrode layer 601.

In a second process (FIG. 6B), a first interface layer 604 is provided on the inert electrode layer 601. The inert electrode layer 601 may be subjected to a cleaning process before the first interface layer 604 is formed.

Then, in a third process (FIG. 6C), a solid electrolyte layer 605 is provided on the first interface layer 604. The solid electrolyte layer 605 may, for example, be doped with metallic material during its formation by co-sputtering solid electrolyte layer material with a metallic material target. For example, the solid electrolyte layer may be doped by codeposition (e.g. co-sputtering) sulfide based chalcogenide material together with a metallic material target including Ag₂S, Ag, Cu₂S, or Cu or which consists of at least one of those materials. Alternatively, the solid electrolyte layer 605 may be doped with metallic material after its formation.

In a fourth process (FIG. 6D), a second interface layer 606 is provided on the solid electrolyte layer 605. The side walls of the solid electrolyte layer 605 may, for example, be covered with material of the first interface layer 604 and of the second interface layer 606 using a conformal deposition step after the patterning/etching of the chalcogenide film (e.g., any CVD (chemical vapor deposition) process like MOCVD, PECVD, LPCVD; SACVD, etc., or any PVD (physical vapor deposition) process having a good side wall coverage) to deposit a film on top of the solid electrolyte layer 605 and also on the sidewalls of the chalcogenide film.

In a fifth process (FIG. 6E), a common reactive electrode layer 607 is provided on the second interface layer 606. Then, a second isolation layer 608 is provided on the reactive electrode layer 607. A contact 610 for contacting the reactive electrode layer 607 is introduced into the second isolation layer 608.

All embodiments discussed in conjunction with the memory device 300 shown in FIG. 3 can also be applied to the manufacturing process shown in FIGS. 6A to 6E.

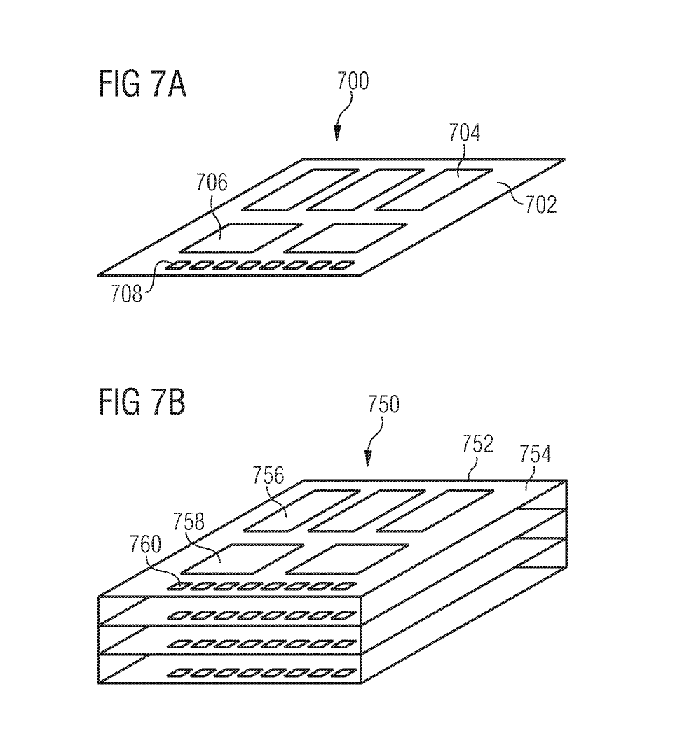

As shown in FIGS. 7A and 7B, in some embodiments, memory devices such as those described herein may be used in modules. In FIG. 7A, a memory module 700 is shown, on which one or more memory devices 704 or integrated circuits in accordance with embodiments of the invention are arranged on a substrate 702. The memory device 704 may include numerous memory cells, each of which uses a memory device in accordance with an embodiment of the invention. The memory module 700 may also include one or more electronic devices 706, which may include memory, processing circuitry, control circuitry, addressing circuitry, bus interconnection circuitry, or other circuitry or electronic devices that may be combined on a module with a memory device, such as the memory device 704. Additionally, the memory module 700 includes multiple electrical connections 708, which may be used to connect the memory module 700 to other electronic components, including other modules.

As shown in FIG. 7B, in some embodiments, these modules may be stackable, to form a stack 750. For example, a stackable memory module 752 may contain one or more memory devices 756, arranged on a stackable substrate 754. The memory device 756 contains memory cells that employ memory elements in accordance with an embodiment of the invention. The stackable memory module 752 may also include one or more electronic devices 758, which may include memory, processing circuitry, control circuitry, addressing circuitry, bus interconnection circuitry, or other circuitry or electronic devices that may be combined on a module with a memory device, such as the memory device 756. Electrical connections 760 are used to connect the stackable memory module 752 with other modules in the stack 750, or with other electronic devices. Other modules in the stack 750 may include additional stackable memory modules, similar to the stackable memory module 752 described above, or other types of stackable modules, such as stackable processing modules, control modules, communication modules, or other modules containing electronic components.

In the following description, further aspects of the present invention will be explained.

An embodiment of the invention relates to the manufacturing of non-volatile memories and more specifically of conductive bridging random access memories (CB-RAM). The concept of this memory type relies on the creation or destruction of at least one conductive bridge formed by metallic or metal rich agglomerates within a chalcogenide glass matrix upon application of a write voltage that is larger than a certain positive threshold voltage to form the bridge.

The bridging link can be erased by applying a more negative voltage than a certain negative threshold voltage. The information stored in this bridge can be read with an intermediate read voltage, which is smaller than the voltage applied for the writing or erasing of the cell. Compared to existing technologies (e.g., DRAM, Flash), this approach offers continued scalability down to very small features sizes combined with non-volatility, fast programming and low power consumption.

From today's view a possible metal to be used for the formation of the conductive bridges is silver (Ag) since it has the highest mobility within the matrix and thus allows building the fastest switching memory. However, it is very difficult to grow Ag smoothly on the chalcogenide material.

A possible approach is to form the CB-junction by depositing the chalcogenide layer (e.g., GeSe), after which a silver (Ag) layer is formed on top of the chalcogenide layer. Then, an optional photo dissolution process may be carried out in order to dissolve the silver (Ag) into the chalcogenide material. The stack is then patterned using, e.g., RIE (reactive ion etch) to form either distinct elements of GeSe/Ag or a common plate of these materials, which is then contacted from the top. The disadvantages of this approach are the poor definition of the features in the RIE due to the rough silver (Ag) films and the necessary long overetch to clear/etch the silver (Ag) remainders in the open areas. In addition, it may be advantageous for the BEOL (back end of line) integration to have a smooth silver containing layer process.

Moreover, upon annealing the CBRAM film stack, especially the metal-doped (e.g., silver doped) chalcogenide material starts to crystallize. This crystallization may, for example, start at the interfaces of the chalcogenide material (especially the interface to the crystalline top electrode or to the crystalline bottom electrode or to any other adjacent crystalline layer). This phenomenon is called heterogeneous crystallization. The interfaces to the dielectric materials (which are used for planarization and isolation purposes) are generally uncritical, since those materials are rather amorphous (e.g., SiOₓ, Si—N).

The above-mentioned crystallization usually shortens the junctions and leads to significant degradation of the electrical switching behavior and thus severely degrades the production yield. Moreover, selenide based chalcogenide systems are prone to a rapid crystallization upon annealing, since there is a homogeneous crystallization and also heterogeneous crystallization.

According to one embodiment of the present invention, the above-described problem is solved by chemically disconnecting the metal-containing chalcogenide layer from the crystalline bottom and also by forming the crystalline top electrode. A sulfide based chalcogenide material may be used. According to one embodiment of the present invention, a co-sputtered sulfide based chalcogenide material can be used, where the chalcogenide material is co-deposited together with silver or copper based material. According to one embodiment of the present invention, a sulfide based chalcogenide material is co-sputtered with an Ag₂S, Ag, Cu₂S, CuS, or Cu target to manufacture the metal-doped chalcogenide material. According to one embodiment of the present invention, a very thin non-crystalline layer of a material is used which is different from the chalcogenide. A suitable material does not crystallize in the same crystalline form (lattice, different lattice parameters, and space group) as the metal-doped chalcogenide material. According to one embodiment of the present invention, a layer consisting of Cu₁₋ₓRuₓ, Cu—N, Cu—O, Ru—O, Ru—N, Ru—O—N, Cu—Ru—O—N, Cu—Ru—N, Cu—Ru—O, Mo—N, Mo—N—Cu, which acts as a crystallization inhibiting layer, but not as a diffusion barrier or isolation layer, is used. Possible other embodiments include Cu or Ru containing layers and other thin ternary metallic layers (having a film thickness in the range of <2 nm).

The application of such a crystallization inhibiting layer is important in order to preserve proper functionality of the cell during BEOL integration. Typically, process temperatures of 300-400° C. are needed for Cu-BEOL, passivation, and packaging, however, for Al-BEOL integration the maximum temperature for chip manufacturing is even higher and thus more critical.

According to one embodiment of the present invention, an active memory cell for CBRAM technology is formed by providing a first electrode, depositing a first thin interface layer (IL1), depositing, for example, a sulfide based chalcogenide material (e.g., Ge—S), which might be deposited in a way that it is doped in-situ with a metal (e.g., Ag or Cu). It can also be doped with metal after completing the chalcogenide deposition without deviating from the scope of this invention.

According to one embodiment of the present invention, a complete capping of the metal-doped chalcogenide material is carried out (which might also be done after defining an array of multiple CBRAM memory cells by means of lithography and etching, for example) by a second thin interface layer (IL2). The interface layer IL1 and IL2 respectively do not necessarily have to consist of the same material, nor do they have to have the same thickness. However, an embodiment of the current invention proposes to use one of the following materials for the IL1 and IL2, respectively: Cu₁₋ₓRuₓ, Cu, Ru, Cu—N, Cu—O, Ru—O, Ru—N, Ru—O—N, Cu—Ru—O—N, Cu—Ru—N, Cu—Ru—O, Mo—N, Mo—N—Cu, which act as a crystallization inhibiting layer, but not as a diffusion barrier or isolation layer. Possible other embodiments include Cu, Ru or Mo containing layers and other thin binary, ternary, or quaternary metallic or semiconducting interface layers containing at least one transition metal (having a film thickness of less than about 5 nm, or even less than about 2 nm). On top of this interface layer a top electrode containing Ag and/or a metallic top contact layer may be deposited. By using this method, the chemical state of the chalcogenide surface has no influence on the growth of the Ag-containing top electrode.

According to one embodiment of the present invention, a method of manufacturing a memory device is provided, the method comprising: providing a semicondutor substrate with electrode contacts; optionally carrying out a substrate cleaning using RF-plasma; depositing a thin interface layer IL1; depositing of chalcogenide material (such as GeSe or GeS) in the range of about 5 to about 500 nm (metal-doped or non-doped); optionally structured formation of chalcogenide material (by means of lithography and etch); depositing of a thin interface layer (IL2); depositing of Ag-containing layer with a thickness in the range of about 10 to about 100 nm and/or top electrode contact layer.

According to one embodiment of the present invention, a metal-doped chalcogenide material (which can include partially nanocrystalline precipitations) is provided which is completely encapsulated by an amorphous or a pseudo-amorphous interface layer material. Parts of this interface layer material can diffuse into the chalcogenide material or into adjacent layers during the BEOL chip manufacturing.

As used herein, the terms “connected” and “coupled” are intended to include both direct and indirect connection and coupling, respectively.

The foregoing description has been presented for purposes of illustration and description. It is not intended to be exhaustive or to limit the invention to the precise form disclosed, and obviously many modifications and variations are possible in light of the disclosed teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined solely by the claims appended hereto.

What is claimed is:

1. An integrated circuit comprising:
a reactive electrode layer;
an inert electrode layer;
a solid electrolyte layer disposed between the reactive electrode layer and the inert electrode layer; and
at least one interface layer disposed between the solid electrolyte layer and the reactive electrode layer and/or between the solid electrolyte layer and the inert electrode layer, wherein material parameters of the at least one interface layer are chosen such that a crystallization of the solid electrolyte layer is at least partially suppressed.

2. The integrated circuit according to claim 1, wherein the crystallization of the solid electrolyte layer results from elevating the temperature of the solid electrolyte layer.

3. The integrated circuit according to claim 1, wherein the material of the at least one interface layer comprises an amorphous material or a pseudo-amorphous material.

4. The integrated circuit according to claim 1, wherein crystallization characteristics of the material of the at least one interface layer and crystallization characteristics of the solid electrolyte layer differ from each other.

5. The integrated circuit according to claim 4, wherein the crystallization characteristics of the material of the at least one interface layer differ from the crystallization characteristics of the solid electrolyte layer in terms of lattice parameters and space group.

6. The integrated circuit according to claim 1, wherein the at least one interface layer does not act as a diffusion barrier.

7. The integrated circuit according to claim 1, wherein the at least one interface layer comprises a binary metallic material, a ternary metallic material or a quaternary metallic material including at least one transition metal.

8. The integrated circuit according to claim 1, wherein the at least one interface layer comprises binary, ternary or quaternary semiconducting material including at least one transition metal.

9. The integrated circuit according to claim 1, wherein the at least one interface layer comprises Cu₁₋ₓRuₓ, Cu, Ru, Cu—N, Cu—O, Ru—O, Ru—N, Ru—O—N, Cu—Ru—O—N, Cu—Ru—N, Cu—Ru—O, Mo—N, Mo—N—Cu, Mo or any combination of these materials.

10. The integrated circuit according to claim 1, wherein the at least one interface layer comprises a first interface layer disposed between the solid electrolyte layer and the reactive electrode layer, and a second interface layer disposed between the solid electrolyte layer and the inert electrode layer.

11. The integrated circuit according to claim 10, wherein the first interface layer and/or the second interface layer has a thickness less than about 5 nm.

12. The integrated circuit according to claim 10, wherein the first interface layer and/or the second interface layer has a thickness less than about 2 nm.

13. The integrated circuit according to claim 10, wherein thicknesses of the first interface layer and of the second interface layer are the same.

14. The integrated circuit according to claim 10, wherein the first interface layer comprises a material that differs from a material of the second interface layer.

15. The integrated circuit according to claim 1, wherein the solid electrolyte layer is completely encapsulated by the at least one interface layer.

16. The integrated circuit according to claim 1, wherein the solid electrolyte layer comprises a sulfide based chalcogenide material.

17. The integrated circuit according to claim 1, wherein the reactive electrode layer comprises silver.

18. The integrated circuit according to claim 1, wherein the solid electrolyte layer has a thickness that ranges from 5 nm to 500 nm.

19. The integrated circuit according to claim 1, wherein the reactive electrode layer has a thickness that ranges from 10 nm to 100 nm.

20. A method of manufacturing an integrated circuit, the method comprising:
forming a composite structure comprising an inert electrode layer, a solid electrolyte layer and a reactive electrode layer which are stacked above each other in this order;
forming a first interface layer overlying the inert electrode layer before forming the solid electrolyte layer; or
forming a second interface layer on or above the solid electrolyte layer before forming the reactive electrode layer; or
forming a first interface layer overlying the inert electrode layer before forming the solid electrolyte layer, and forming a second interface layer on or above the solid electrolyte layer before forming the reactive electrode layer,
wherein material parameters of the at least one interface layer are chosen such that a crystallization of the solid electrolyte layer is at least partially suppressed.

21. The method according to claim 20, wherein the crystallization of the solid electrolyte layer results from elevating a temperature of the solid electrolyte layer.

22. A method of manufacturing an integrated circuit, the method comprising:
forming an inert electrode layer;
forming a first interface layer on or above the inert electrode layer;
forming a solid electrolyte layer on or above the first interface layer;
forming a second interface layer on or above the solid electrolyte layer; and
forming a reactive electrode layer on or above the second interface layer,
wherein material parameters of the first interface layer and the second interface layer are chosen such that a crystallization of the solid electrolyte layer is at least partially suppressed.

23. A method of manufacturing an integrated circuit, the method comprising:
forming a reactive electrode layer;
forming a first interface layer on or above the reactive electrode layer;
forming a solid electrolyte layer on or above the first interface layer;
forming a second interface layer on or above the solid electrolyte layer; and
forming an inert electrode layer on or above the second interface layer,
wherein material parameters of the first interface layer and the second interface layer are chosen such that a crystallization of the solid electrolyte layer is at least partially suppressed.

24. A memory module comprising at least one integrated circuit:
a reactive electrode layer, an inert electrode layer, and a solid electrolyte layer being disposed between the reactive electrode layer and the inert electrode layer; and
at least one interface layer being disposed between the solid electrolyte layer and the reactive electrode layer or between the solid electrolyte layer and the inert electrode layer, or being disposed between the solid electrolyte layer and the reactive electrode layer and between the solid electrolyte layer and the inert electrode layer, wherein material parameters of the at least one interface layer are chosen such that a crystallization of the solid electrolyte layer is at least partially suppressed.

25. The memory module according to claim 24, wherein the memory module is stackable.
